(19) United States
(12) Patent Application Publication
(10) Pub. No.: US 2026/0213762 A1
(43) Pub. Date: Jul. 23, 2026

(54) THIRD ORDER HOLD (TOH) DIGITAL TO ANALOG CONVERTER AND METHOD FOR APPLYING PIECEWISE CATMULL-ROM SPLINES IN THE ANALOG DOMAIN (TOH CR)

(71) Applicant: Bojidar Borissov Kounov, London (GB)

(72) Inventor: Bojidar Borissov Kounov, London (GB)

(21) Appl. No.: 19/444,822

(22) Filed: Jan. 9, 2026

(30) Foreign Application Priority Data
Jan. 15, 2025 (GB) 2500492.0

(51) Int. Cl. H03M 1/10; G06F 17/16; G10L 19/02

(52) U.S. Cl. CPC H03M 1/1023; G06F 17/16; G10L 19/02

(57) ABSTRACT

The present invention introduces a DAC process or system for transferring a digital signal to a continuous analog signal using polynomials of second and higher order or Catmull-Rom splines to connect each two consecutive sample values. It includes a feedback mechanism for error correction, ensuring smooth and accurate reconstruction.

### FIELD OF THE INVENTION

The present invention is in the field of digital to analog conversion systems and processes.

### BACKGROUND OF THE INVENTION

The revolution of digital audio has transformed the way we create, distribute, and consume music and sound. From the advent of digital recording technologies to the proliferation of streaming services, digital audio has revolutionized the industry. However, a critical aspect of this revolution is the conversion of digital signals into analog signals, which presents various challenges and complexities.

Digital audio signals are discrete representations of sound, characterized by binary data streams. To be heard through traditional analog systems, these original digital signals must be converted back into analog form. This process, however, is fraught with challenges.

When an analog signal is converted to digital, it becomes a discrete representation of the original signal. Thus, the amplitude is only known at certain sample time intervals. To recreate the analog signal, a digital-to-analog converter (DAC) holds each sample value until the next arrives, resulting in a staircase waveform (zero-order hold) or uses a linear process (first-order hold). The staircase building blocks and the linear ramps to lesser extent introduce significant energy in the harmonics. These harmonics mostly originate at the point of junction (further called a knot point). Therefore, if we take a sinusoidal signal, convert it into digital, and then reproduce it back, a frequency spectrum analysis of the resulting a signal reveals additional frequencies beyond the original sinusoidal component.

There exists a need to achieve a smooth, continuous-time and -values analog signal with minimum added artificial harmonics from the digital-to-analog conversion process itself.

### SUMMARY OF THE INVENTION

In the broadest possible sense, the present invention is directed to a new DAC process or system for transferring a digital signal to a continuous analog signal domain by employing piecewise cubic splines, including the Catmull-Rom cubic splines, to connect consecutive sample points.

The present invention provides a DAC system or a DAC process for transferring digital signal to a continuous analog signal. It is proposed that, for each sampling interval, a polynomial function be used in the analog domain, where the polynomial coefficients are computed in the digital domain by a dedicated DSP, and the time integration of the coefficients and summation of the polynomial terms are performed in the analog domain.

In some embodiments, feeding the polynomial coefficients in a digital form into multilevel DACs outputs voltages or currents linearly proportional to the input amplitudes (the calculated polynomial coefficients).

In some embodiments, the outputted constant currents or voltages from the DACs are integrated over time by a capacitor (in the case of current) or by operational amplifier configured as a voltage integrator (op-amp integrator) in the case of voltage. Further summation of the polynomial terms is performed by a summing op-amp summing with multiple inputs, producing the desired polynomial value in the analog domain.

A key aspect of the present invention introduces an error correction mechanism. This includes a feedback loop, where an analog-to-digital converter (ADC) converts the final analog signal back into digital form. The DSP compares this feedback signal to the intended signal and adjusts the polynomial coefficients dynamically to mitigate integrated drift and DC offset errors, ensuring the output remains smooth and accurate.

There is provided a method of performing a Third Order Hold (TOH) digital-to-analog signal conversion, the method comprising the steps of:
a. providing a digital signal,
b. preforming a digital signal determination of polynomial coefficients for each polynomial term;
c. mapping the polynomial coefficients from b to a discrete set of levels forming unique signal levels in the analog domain by using multilevel DACs (one for each coefficient);
d. two signal integrators in series would produce a quadratic function of time and by increasing the number of integrators in series we can achieve higher order of the desired spline function;
e. integrating by time each coefficient with the necessary number of op-amp integrators to achieve the needed order of the term and then summing the resulting values employing a summing op-amp with multiple signal inputs.

It would be clear to the skilled person that 3 (three) in series would create a cubic function of time (third order term) as contemplated herein.

In an aspect of the present invention, there is a background invention-U.S. Published Patent App. No. US20060145902A1, describing what is known as FOH (first order hold), and its scope is limited to linear (ramp) process.

U.S. Pat. No. 5,510,851A describes using a Catmull-Rom piecewise spline method for dynamically adjusting the luminance of colour channels digitally. It uses Catmull-Rom splines to interpolate between a grid of luminosity sample points, producing smooth correction surfaces, and the interpolation occurs entirely in the digital domain to generate correction data streams.

U.S. Pat. No. 10,102,181B2 describes efficient Catmull-Rom interpolation methods for determining interpolated values from an array of digital data points. The interpolation is designed for digital signal processing and is not directly tied to analog signal reconstruction.

The present invention considers using Catmull-Rom splines or similar higher-order interpolation methods directly in the analog domain, not otherwise contemplated in the state of the art especially if applied to digital-to-analog reconstruction or signal synthesis.

### Advantages of the Present Invention

1. Extension of Spline Concepts to Analog:
   Catmull-Rom splines are traditionally used in the digital domain for interpolation.
   Adapting these concepts for real-time, continuous-time analog signal reconstruction would require novel methods to implement spline-based calculations in hardware or mixed-signal systems.
2. Improved Signal Reconstruction:
   Higher-order holds like splines could potentially reconstruct smoother, more accurate analog signals compared to conventional zero- or first-order holds.
   This could be particularly beneficial in high-fidelity audio systems, precise instrumentation, or advanced communication systems.
3. Potential for New Applications:
   Analog-domain spline interpolation could find use in:
      Ultra-low-distortion audio DACs.
      High-resolution image or video signal reconstruction.
      Advanced sensor signal conditioning for robotics or scientific instruments.
4. Limited Existing Work:
   Most spline interpolation methods remain in the digital realm because analog implementation of such computationally intensive methods has historically been impractical, which has changed with the advances of the technologies.

### DESCRIPTION OF THE DRAWINGS

FIG. 1 depicts a diagram of the TOH^{CR} digital to analog conversion process as described herein.

FIG. 2 depicts building the analog signal by using Catmull-Rom splines.

### DETAILED DESCRIPTION OF THE INVENTION

Throughout this disclosure, various scientific publications, patents and published patent specifications are referenced by an identifying citation. The disclosures of these publications, patents and published patent specifications are hereby incorporated by reference into the present disclosure to more fully describe the state of the art to which this disclosure pertains.

As used herein, certain terms may have the following defined meanings.

As used in the specification and the claims, the singular form “a,” “an” and “the” include singular and plural references unless the context clearly dictates otherwise.

As used herein the term “sampling time” refers to the interval at which an analog signal is sampled in order to convert it into a digital signal and is measured in in terms of seconds, milliseconds, microseconds or nanoseconds. The sampling time determines the “sampling rate”, which is the number of samples taken per second.

As used herein the term “digital signal” refers to a signal data, as a sequence of discrete values, measured at the sample points, and rounded to the nearest available value from a predetermined finite number of values. Digital signals are often represented in binary form.

As used herein the term “analog signal” refers to any continuous by time and continuous by value signal such as continuous electrical signal, for which the time varying feature of the signal is a representation of some other time varying quantity or analogous to another time varying signal. As an example, in an analog audio signal, the instantaneous signal voltage varies with the pressure of the sound waves. In some embodiments, the analog signal is an audio signal.

As used herein, the term “comprising” means including, made up of, composed of encompass, consist of, constitute and incorporate.

All numbers or numerals as used herein that indicate amounts, ratios of materials, physical properties of materials, and/or use are to be understood as modified or qualified by the term “about,” except as otherwise explicitly indicated.

As used herein, the term “about” includes the recited number or number and +/−10% from the recited numeral or number. By way of non-limiting example, the term “about ten (10)” would encompass nine (9) to eleven (11) or 9-11.

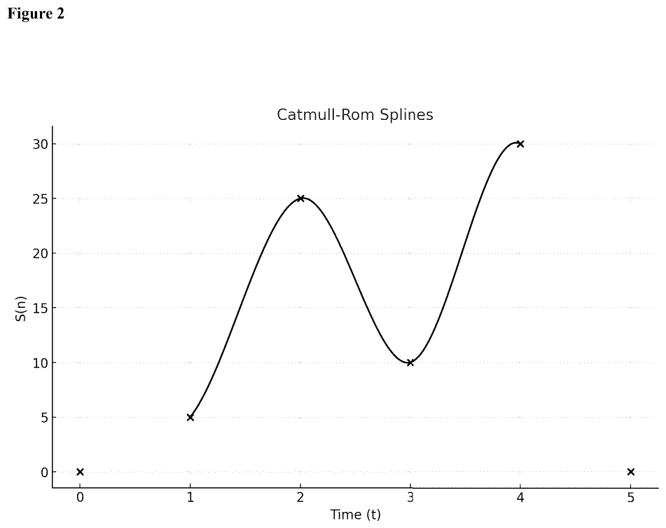

The term “substantially” refers to up to 80% or more of an entirety. As an example, substantially linear refers to up to 80% or more of a reference pattern such as a sinusoidal curve. By way of a particular simulated example, substantially linear refers to up to 80% or more of a reference curve as shown in FIG. 2. In some embodiments, the substantially linear digital-to-analog signal conversion is relative to a digital signal as in FIG. 2. In some embodiments, the present method leads to statistically significant linear digital-to-analog signal conversion. Here the term linear is used on a micro level, within the context of a single sample time period, not to be referred to the signal in general. In some embodiments, the present method leads to statistically significant improvement in digital-to-analog signal conversion.

Recitation of ranges of values herein are not intended to be limiting, referring instead individually to any and all values falling within the range, unless otherwise indicated, and each separate value within such a range is incorporated into the specification as if it were individually recited herein.

As used herein, the term “at least one,” unless otherwise indicated, refers to one or more steps, determinations, signal assessments, examinations, sample points or spaces, which can be used in the methods or systems of the present invention.

As used herein, the term “two consecutive,” unless otherwise stated, refers to two immediately such as contiguously following, in respect of time, discrete or unique values, steps, determinations, signal assessments, examinations, amplitudes, sample points or spaces, which can be used in the methods or systems of the present invention.

As used herein the term “difference” or “mathematical difference” refers to the result of an operation such as mathematical determination which is obtained by subtracting two numbers, values or points such as, for example two consecutive sampling values or points.

As used herein the term “digital amplitude difference” is a digital data representation of the amplitude difference of two discrete values. Each sample interval has two sample points. We can call the first one t and second one t+1. The values of these sample points are stored in digital data format, in most cases binary. For example, a single second (one or 1) cd audio data will have 44100 sampling points, where each one may have amplitude value among 65536 values (16 bits).

The method or system described herein is sometimes referred to as TOH^{CR} DAC process or TOH^{CR} DAC system.

As used herein the term “summation” refers to the addition of a sequence of numbers or samples such as two consecutive samples or more, the result is their sum or total.

It has surprisingly been discovered that a DAC system can be modified to enable the transfer of digital signal to a smooth continuous analog signal, between each two consecutive sampling points.

In particular it has been discovered that one can make a new TOH^{CR} digital to analog conversion process that does not hold a discrete signal data value constant, awaiting for the next value to arrive and jump to it as can be seen in FIG. 2, but rather takes two consecutive values and using a cubic spline continuous process starts from the first sample value and arrives at the next sample value for the available sampling time.

In a traditional multilevel DAC, after referred to in our example as a, ladder R-2R DAC, in the analog time domain the signal is not continuous by value and arbitrary continuous by time. In other words, in the traditional ladder R-2R DAC, in the analog time domain the signal rebuilds by “jumping” between discrete values. Without wishing to be bound by theory, this phenomenon is considered to be a consequence of the DAC effectively holding a value until the next digital data is fed into it and produces the next discrete value, forming a staircase like representation of the original analog signal. The signal values are only known at certain, regularly spaced discrete time intervals determined by the sample rate of the DAC and the number of possible discrete values is predetermined by the number of bits in the digital data signal (bit-depth) (like for example in the cd audio these are 16-bits depth and 44.1 kHz sample rate).

The TOH^{CR} digital to analog conversion process of the present invention does not hold the discrete values constant.

In particular, the TOH^{CR} process of the present invention does not hold the discrete values constant, awaiting, for the next value to arrive and jump to it. More in particular, the TOH^{CR} process of the present invention does not hold the discrete values constant, awaiting, for the next value to arrive and jump to it, but takes four consecutive values and using the Catmull-Rom cubic splines starting from the second sample value and arrives at the third sample value for the available time between them—FIG. 2, creating a smooth signal path, that has C⁰ and C¹ continuity.

Without wishing to be bound by theory, a time integrating device can used either a capacitor or voltage integrating op-amp. From a practical consideration present embodiments will further focus on using op-amp, but for the sake of completeness both processes are discussed.

When a constant current is fed into a capacitor, the voltage across the capacitor will increase in a linear pattern. This behavior is based on the relationship defined by the capacitor's fundamental equation:

$$I = C \frac{dV}{dt}$$

Where:
I is the current flowing into the capacitor.
C is the capacitance of the capacitor.
dV/dt is the rate of change of voltage across the capacitor.
   When a constant current I is applied, the equation can be rearranged to solve for the voltage change over time:

dV/dt=I/C
Since I and C are constants, the rate of change of voltage dV/dt is also constant. Integrating both sides with respect to time t gives:

V(t)=(I/C)t+Vo
Where V(t) is the voltage across the capacitor at time t, and Vo is the initial voltage across the capacitor at t=0.

This equation shows that the voltage V(t) increases linearly with time when a constant current is applied. The slope of the linear increase is determined by the ratio I/C, meaning that for a given capacitor, the voltage increases at a rate proportional to the applied current and by manipulating the current, we can change the voltage linearly starting from a discrete value V(t) and arriving at a discrete value V(t+1). In order to construct the analog signal, there must be a unique match between the voltage difference of these discrete values of the consecutive discrete values (voltage differential) and the constant current corresponding to this voltage differential.

Instead of using a VCCS and capacitor as integrator one can use operational amplifier configured as an integrator with input resistor R, feedback capacitor C and Vin(t) is the input voltage as a function of time.

$$Vout ( t ) = - \frac{1}{R C} {\int }_{0}^{t} V i n ( t ) d t$$

If Vin(t) is constant for a time t, then the output voltage Vout of an integrator circuit will be a linear function of time.

$$Vout ( t ) = - \frac{1}{RC} Vconstant * t$$

Furthermore two signal integrators in series would produce a quadratic function of time and by increasing the number of integrators in series we can achieve higher order of the desired spline function. Thus 3 in series would create a cubic function of time.
The first op-amp is configured as integrator, meaning its output is integral of the input signal over time. If the input signal is constant Vin, the output will be:

$${V}_{o u t 1 ( t )} = - \frac{1}{R {C}_{1}} {V}_{i n} * t$$

Now the output of the first op-amp is fed into the input of a second op-amp, also configured as integrator. Its output will be the integral of the linear function of the first one:

$${V}_{o u t 2 ( t )} = - \frac{1}{R {C}_{2}} \int {V}_{o u t 1 ( t )} d t = \frac{{V}_{i n}}{2 {R}^{2} {C}_{1} {C}_{2}} {t}^{2}$$

And for 3 op-amps integrators in series:

$${V}_{o u t 3 ( t )} = - \frac{{V}_{i n}}{6 {R}^{3} {C}_{1} {C}_{2} {C}_{3}} {t}^{3}$$

To normalize the denominators to 1 we need the values for Cn=1/(n·R).

$$for example {C}_{3} = \frac{1}{3 R}$$

Further as the output signal is inverted one can use second operational amplifier configured as in inverter or one can invert the polynomial coefficients in the digital domain (using DSP for example).

In the analog domain, the summing and integration of analog signals most likely will be not a perfect process and is likely to exhibit non-linearity and asymmetry in errors. Further these errors will be integrated over time and may lead to variable DC component in the output signal. This computational error may be mitigated by implementing a back feed. For example an analog to digital converter may be used to convert the final analog signal back into digital and its value could be compared into the DSP. The later adjusts the sample amplitudes with the feedback error.

The digital clocks of all DACs and the ADC must be synchronized, by using a single clock source.

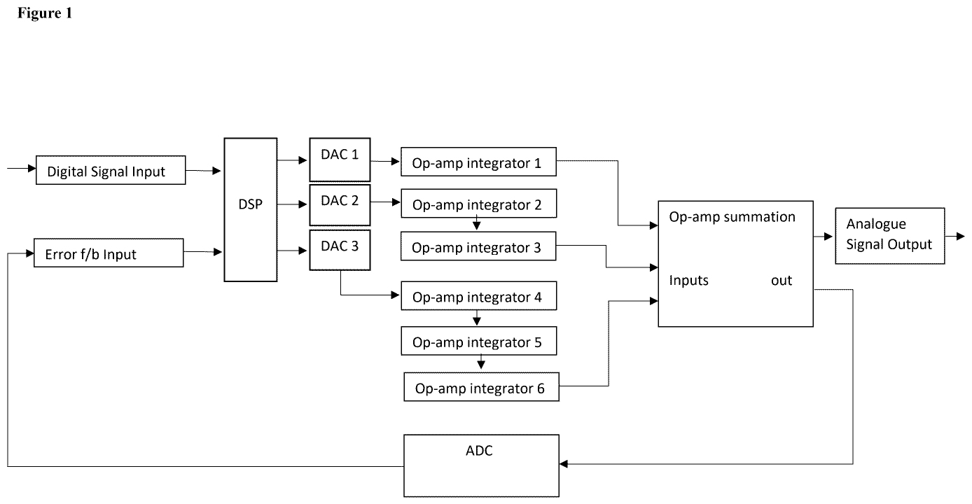

A schematic of the system of the present invention is presented in FIG. 1. According to an aspect of the present invention, there is provided a digital-to-analog signal conversion system comprising:
a. a digital signal source;
b. a DSP used to calculate the polynomial coefficients;
c. multilevel DACs to produce map the digital coefficients to analog voltage values;
d. multi-inputs voltage summing op-amp and voltage integrating op-amps.
e. ADC-analog to digital convertor, used to provide feedback for error correction.

In the present description, it is understood that terms such as “first,” “second,” “top,” “bottom,” “up,” “down”, “upper”, “lower”, “above”, “below”, “beneath”, “front”, “back”, “over”, “under”, “left”, “right” etc. are used with reference to the orientation of some of the components of the system of the present invention. Since constituents or components in various embodiments described here can be positioned in a number of different orientations, locations in a circuit, directional terminology is used for purposes of illustration only and is in no way limiting. The directional terminology is intended to be construed broadly, and therefore should not be interpreted to preclude components being oriented in different ways. Reference here can be made to for example the scheme in FIG. 1.

Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the disclosure claimed. It will also be appreciated that the method(s), system(s), DAC(s), capacitor(s) may be subject to numerous rearrangements, modifications and substitutions without departing from the scope of the present disclosure as set forth and defined by the following claims.

In order that the invention may be readily understood and put into practical effect, particular embodiments will now be described by way of the following non-limiting simulated examples.

It is contemplated by the present invention that the digital-to-analog conversion (DAC) process is intended to and can be configured to transform a digital signal, which is represented as discrete binary values, back into continuous analog signal as accurate as practically possible.

The disclosure illustratively described herein can suitably be practiced in the absence of any element or elements, limitation or limitations, not specifically disclosed herein. Thus, for example, the terms “comprising”, “including,” containing,” etc., shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the disclosure claimed. It will also be appreciated that the system(s), method(s), use(s) and apparatus(s) may be subject to numerous rearrangements, modifications and substitutions without departing from the scope of the present disclosure as set forth and defined by the following claims.

The original analog signal can be viewed as a continuous function of time ƒ(t). As an integral of a derivative of a function is simply the function plus a constant we can rewrite:

$$\begin{matrix}1 ) & \\ f ( t ) = \int \frac{df ( t )}{d t} dt - constant = \int d f ( t ) - constant & \end{matrix}$$

When dƒ(t) is not approaching zero, we can rewrite:
   2)

$$f ( t ) = {\sum }_{t = 0}^{n} Δ f ( t ) ,$$

where t is having now a discrete value from 0 to n and Δƒ(t) is the change of ƒ(t) within each time interval t.

The first function is a continuous and the second function is discrete by time.

To reconstruct the original analog function we use a hybrid of the two functions, we use continuous integration of a non-approaching zero Δƒ(t). The expression

$$\frac{Δ f ( t )}{Δ t}$$

represents the average rate or change of the function ƒ(t) over the interval Δt.

$$3 ) f ( t ) = \int \frac{Δ f ( t )}{Δ t} dt ( - constant c )$$

For each sample interval i, the ratio

$$\frac{Δ f ( {t}_{i} )}{Δ t}$$

will be a constant.

The value of the function ƒ(t) at the time t_{c}, which falls within sampling interval n can be represented as

$$4 ) f ( {t}_{c} ) = {\sum }_{i = 1}^{n - 1} Δ f ( ti ) + {\int }_{0}^{{t}_{c - ( n - 1 )}} \frac{Δ f ( t )}{Δ t} dt , as for i ∈ ( 1 ; n - 1 ) ; f ( ti ) = \frac{Δ f ( ti )}{Δ t} {\int }_{0}^{Δ t} dt = Δ f ( ti )$$

As the digital signal is a string of discrete values equally spaced over time, we can easily calculate Δƒ(t) for each sampling interval −Δt. It is important to note that the calculation of Δƒ(t) could be performed in the digital domain.

It is envisaged by the present invention that by continuously integrating this constant in the analog domain there can be achieved a linear and continuous in time and value signal as a building block for ƒ(t) during the given sampling interval Δt.

When Δƒ(t) becomes smaller and smaller, the rebuild analog signal will be closer and closer to the original analog signal. The constant −c is

$${\sum }_{i = 1}^{n - 1} Δ f ( ti ) ,$$

initially zero and thereafter the end value of ƒ(t) from the previous sample interval. As we are going to use a capacitor as integrating device in the analog domain, the electric potential of the capacitor in volts at t=0 will be the constant −c at the starting point and it will self-adjust thereafter.

Polynomial of higher order: instead of taking the first integral from first derivate and having a polynomial of first order as a building block, there can be used 3 consecutive sampling points and to find the second derivative and integrate the same twice (it will be a constant during each sampling interval). In such a case the building block for each sample interval will be a quadratic function:

$$5 ) f ( t ) = \int \int \frac{{Δ}^{2} f ( t )}{Δ {t}^{2}} dtdt = \frac{1}{2} Δ f ( t ) {t}^{2} - {C}_{1} t + {C}_{2} ,$$

where
The constant C₂ has the same meaning as in 4) and the second derivative is a constant during each sample interval

$$\frac{{Δ}^{2} f ( t )}{Δ {t}^{2}} = f ( 3 ) - 2 f ( 2 ) + f ( 1 ) and Δ t = 1$$

is a simplification (one sample interval is considered one unit of time).

$${C}_{1} = \frac{1}{2} ( 3 f ( 1 ) - 4 f ( 2 ) + f ( 3 ) ) ,$$

where ƒ(i) are the values of the 3 consecutive sample points. The derivation of this coefficient is made in a local coordinate system with its center at the first sampling point.
A polynomial of order of n using n+1 consecutive sample/sampled points, where the n^{th} order derivative will be:

$$6 ) {Δ}^{n} f ( t ) = {\sum }_{k = 0}^{n} - {1}^{n - k} ( \begin{matrix}n \\ k\end{matrix} ) f ( t + k ) , where ( \begin{matrix}n \\ k\end{matrix} ) = \frac{n !}{k ! ( n - k ) !}$$

is the binomial coefficient of the polynomial.
By using local piecewise polynomial segments (splines) of different orders, it is possible to improve the accuracy of the process and reduce the unwanted harmonic distortions, but they still remain. Δt the sampling points (knot points), the adjacent pieces form an angle (there is no C¹ continuity), which is a source of unwanted harmonic artefacts.

TOH^{CR} and C¹ continuity: instead of using cubic splines that meet the boundary conditions to pass throughout all four points, we can use cubic splines that pass only through second and third points and implement two more boundary conditions that achieve smoothness at the knot points, i.e. the Catmull-Rom cubic splines—FIG. 2.
The Catmull-Rom spline Sn₍ₜ₎ is described by the following equation:

$${Sn}_{( t )} = ( 2 {t}^{3} - 3 {t}^{2} + 1 ) {Y}_{( n )} + \frac{1}{2} ( {t}^{3} - 2 {t}^{2} + t ) ( {Y}_{( n + 1 )} - {Y}_{( n - 1 )} ) + ( - 2 {t}^{3} + 3 {t}^{2} ) {Y}_{( n + 1 )} + \frac{1}{2} ( {t}^{3} - {t}^{2} ) ( {Y}_{( n + 2 )} - {Y}_{( n )} ) ,$$

where Y₍ₙ₎ are the values of the data points.
In a local coordinate system with center with coordinates of (tₙ=0;Y′₍ₙ₎=0) the equation will be simpler. To translate the data point values into local coordinate system one should subtract the value of Y₍ₙ₎ from the values of all data points in the equation. This will simplify the above equation to:

$${Sn}_{( t )} = \frac{1}{2} ( {t}^{3} - 2 {t}^{2} + t ) ( {Y}_{( n + 1 )}^{′} - {Y}_{( n - 1 )}^{′} ) + ( - 2 {t}^{3} + 3 {t}^{2} ) {Y}_{( n + 1 )}^{′} + \frac{1}{2} ( {t}^{3} - {t}^{2} ) {Y}_{( n + 2 )}^{′}$$

The above spline function can be further rearranged as:

$${Sn}_{( t )} = \frac{1}{2} ( {Y}_{( n + 1 )}^{′} - {Y}_{( n - 1 )}^{′} ) t + ( 2 {Y}_{( n + 1 )}^{′} + {Y}_{( n - 1 )}^{′} - \frac{1}{2} {Y}_{( n + 2 )}^{′} ) {t}^{2} + \frac{1}{2} ( {Y}_{( n + 2 )}^{′} - {Y}_{( n - 1 )}^{′} - 3 {Y}_{( n + 1 )}^{′} ) {t}^{3} ,$$

which translates into calculating three coefficients for each sample interval in the digital domain.

$${Sn}_{( t )} = {C}_{0} \cdot t + {C}_{1} {t}^{2} + {C}_{2} {t}^{3}$$

Taking into account the error correction the above equation becomes:

$${Sn}_{( t )} = {C}_{0} \cdot t + {C}_{1} {t}^{2} + {C}_{2} {t}^{3} - {E}_{c ( n )} ,$$

where
   E_{c(n)} is the difference between the registered by ADC Sₙ₋₁₍ₜ₎ signal value and Y₍ₙ₋₁₎ and the coefficients C₀, C₁ and C₂ are calculated by the DSP and fed into DAC1, DAC2 and DAC3 (FIG. 1) respectively.

### Surprising and Unexpected Findings and Advantages of the Present Invention

In the analog domain the present system and process offer smooth continuous signal processing. The signal formed by the Catmull-Rom splines (pathways connecting the sample values) would have less energy in the artificial harmonics in comparison to the ZOH, FOH and higher order polynomials, not utilizing Catmull-Rom splines. Thus, the signal reconstruction noise would be significantly less and easier to filter when using the present invention.

The embodiments herein surprisingly and unexpectedly result in a method able to transfer a digital signal to a continuous analog signal domain. Results also provided a much, needed clarification of how to optimise existing multilevel DAC systems such as the traditional r2r DAC system in order to generate a substantially better digital-to-analog signal.

In addition, embodiments of the described method and system were able to deliver a substantially continuous digital signal transfer path with the desired precision of the analog sound quality output.

What is claimed is:

1. A method for digital-to-analog signal reconstruction, comprising:
a) calculating cubic spline coefficients in the digital domain for interpolating between discrete digital samples;
b) using said coefficients to generate a piecewise cubic polynomial representation of the signal;
c) ensuring C1 continuity of the reconstructed analog signal;
d) implementing the interpolation in the analog domain using:
i) a series of operational amplifier integrators to compute higher-order polynomial terms,
ii) an operational amplifier summator to combine the computed terms into the final interpolated analog signal; and
e) providing a feedback loop from the analog domain to the digital signal processor (DSP) to adjust the coefficients dynamically and correct errors, said corrected errors including integrated drift and DC offset errors.

2. A method according to claim 1, wherein the interpolation process is defined as a third-order hold with Catmull-Rom spline interpolation (TOH^{CR}).

3. A method according to claim 2, wherein the Catmull-Rom spline coefficients are calculated in real-time from four consecutive digital samples.

4. A method according to claim 1, further comprising the step of scaling the spline coefficients based on the desired output amplitude and frequency range before feeding them into the analog interpolation circuit.

5. A system for digital-to-analog signal conversion, comprising:
a) a digital processor configured to calculate cubic spline coefficients;
b) an analog reconstruction circuit comprising:
i) a plurality of operational amplifier integrators arranged to compute polynomial terms of varying orders,
ii) an operational amplifier summator configured to combine the polynomial terms;
c) a feedback loop connecting the analog reconstruction circuit to the digital processor to dynamically adjust cubic spline coefficients and correct analog reconstruction errors whereby the system ensures continuity in the reconstructed analog signal's first derivative.

6. A system according to claim 5, wherein the analog interpolation process achieves higher-order holds, including but not limited to second-order holds, third-order holds, and Catmull-Rom spline-based holds.

7. A system according to claim 5, wherein the operational amplifier integrators are configured to perform real-time integration of the spline polynomial terms, with the summation stage combining these terms to reconstruct the analog signal.

8. A generalized higher-order hold method for digital-to-analog signal reconstruction, comprising:
a) calculating polynomial coefficients for a piecewise interpolation in the digital domain;
b) using operational amplifiers in the analog domain to perform term-wise integration and summation for signal reconstruction;
c) providing a feedback loop to dynamically adjust coefficients and correct for analog reconstruction errors, including integrated drift and DC offset;
d) ensuring continuity up to the first derivative of the reconstructed analog signal.

9. A method according to 8, wherein the polynomial coefficients are determined for second-order holds, third-order holds, or higher-order holds to achieve smooth and accurate signal reconstruction.

10. A system according to claim 5, wherein the analog interpolation circuit is modular, allowing adaptation for different polynomial orders by adding or removing operational amplifier integrator stages.

11. A system according to claim 5, wherein the analog interpolation circuit is implemented using precision operational amplifiers to minimize noise and distortion during the interpolation process.

12. A system according to claim 5, further comprising TOH^{CR} interpolation within the analog reconstruction circuit to ensure that the analog output is a continuous and smooth waveform suitable for applications requiring high precision and low distortion.

13. A method according to claim 1, further comprising a TOH^{CR} process optimized for use in high-fidelity audio systems, thereby ensuring minimal harmonic distortion and preservation of the original signal's spectral integrity.

14. A computer-readable medium storing instructions that, when executed by a digital signal processor, perform the method of claim 1, further including the calculation of Catmull-Rom spline coefficients and their application in analog signal reconstruction.

15. A method according to claim 8, wherein the analog interpolation process is enhanced with feedback mechanisms to adjust the operational amplifier stages for maintaining accuracy across varying signal amplitudes and frequencies.
